(19) United States
(12) Patent Application Publication
(10) Pub. No.: US 2012/0013020 A1
(43) Pub. Date: Jan. 19, 2012

(54) MEMS Device Comprising a Hermetically Sealed Cavity and Devices Obtained Thereof

(75) Inventors: Bin Guo, Leuven (BE); Luc Haspeslagh, Lubbeek-Linden (BE)

(73) Assignee: IMEC, Leuven (BE)

(21) Appl. No.: 13/181,833

(22) Filed: Jul. 13, 2011

Related U.S. Application Data
(60) Provisional application No. 61/364,561, filed on Jul. 15, 2010.

(51) Int. Cl. H01L 23/48; H01L 21/31

(52) U.S. Cl. 257/774; 438/763; 257/E21.24; 257/E23.011

(57) ABSTRACT

A MEMS device is disclosed comprising a cavity containing a MEMS component, the cavity being formed in a dielectric layer stack having a thickness t_{d}, whereby the cavity and the dielectric layer stack are sandwiched between a substrate and a sealing dielectric layer having a thickness tₛ, and whereby the MEMS component is enclosed by at least one trench extending over the thickness t_{d} of the dielectric layer stack and of the sealing dielectric tₛ.

### CROSS-REFERENCE TO RELATED APPLICATIONS

This application claims priority under 35 U.S.C. § 119(e) to U.S. Provisional Patent Application Ser. No. 61/364,561, filed on Jul. 15, 2010, the full disclosure of which is incorporated herein by reference.

### FIELD

The present disclosure relates to Micro Electro Mechanical systems, also known as MEMS devices, comprising a hermetically sealed cavity. In particular this disclosure relates to MEMS devices formed on a semiconductor-on-insulator (SOI) substrate.

### BACKGROUND

Micro-Electro-Mechanical Systems (MEMS) refers to the integration of micromechanical components such as cantilevers, sensors, actuators, with electronics on a common substrate through microfabrication technology. The electronic components are fabricated using integrated circuit (IC) manufacturing technology, whereas the micromechanical components are fabricated using “micromachining” technology compatible with the electronic components. This micromachining technology selectively etches away parts of the substrate or adds new structural layers to form the micromechanical components.

The micromechanical components are contained in a cavity which, for many applications, needs to have a well-controlled ambient. Hence this cavity should be hermetically sealed from the environment wherein the MEMS device is to operate. The sealing of the cavity is ideally done before the substrate is diced to yield the individual MEMS devices. Typically thin film capping is used to form a membrane overlying and sealing the cavity containing the MEMS component.

### SUMMARY

If a silicon layer of a Silicon-on-Insulator (SOI) substrate is used as structural layer for micromachining the MEMS component, the hermetic sealing of the cavity can be questioned. As the sidewalls of the cavity are, at least partly, formed in the silicon dioxide layer separating the silicon layer from the carrier substrate, these sidewalls will constitute leakage paths between the cavity and the environment in which the MEMS device is placed, e.g. during manufacturing or when in operation.

Silicon dioxide is known to have a low hermeticity as indicated by the low activation energy of 0.3 eV for hydrogen diffusion. This hermeticity may even be further degraded during subsequent processing of the MEMS device. In addition silicon dioxide is known to absorb moisture and oxygen, even at room temperature.

Hence there is a need to form a hermetically sealed cavity, in particular when this cavity is, at least partly formed in a silicon dioxide layer.

In an example aspect, the disclosure relates to a method for manufacturing a MEMS device comprising a hermetically sealed cavity containing a MEMS component whereby the method comprises providing a substrate having on a major surface a stack of a structural layer on a first dielectric layer, patterning the structural layer to form a MEMS component, forming a second dielectric layer overlying the MEMS component, forming a sealing dielectric layer overlying the second dielectric layer, forming in the stack of dielectric layers a trench extending to the substrate while enclosing the MEMS component, depositing a membrane layer overlying the sealing layer thereby filling the trench, and patterning the membrane layer thereby forming a membrane at the location of the MEMS component and an electrode covering the filled trench.

The structural layer can be a single layer or a stack of layer of semiconductive materials, such as silicon-germanium or silicon. Alternatively the structural layer can be a single layer or stack of layers of a conductive material such as titanium or nickel.

The method can further comprise removing the first and second dielectrics selective to the sealing dielectric layer, thereby creating underneath the membrane the cavity which contains now the MEMS component. In a particular embodiment openings are formed through the membrane and the sealing dielectric layer at the location of the MEMS component, through which openings the first and second dielectrics are then removed. After the removal of the first and second dielectrics these openings are sealed.

The sealing dielectric may be selected from the group of silicon-carbides or alumina-oxides when the first and second dielectrics are silicon-oxide.

The substrate can be a Semiconductor-On-Insulator (SOI) substrate, in which case the semiconductor layer thereof is the structural layer used for micromachining the MEMS component and the insulating layer separating the semiconducting layer from the substrate is the first dielectric layer. In case of a silicon-on-insulator substrate being a stack of a silicon layer, a silicon-oxide layer and a silicon carrier substrate, the silicon layer is used as structural layer and the silicon-oxide layer is used as first dielectric layer.

The membrane layer may be formed in silicon-germanium SiₓGe₁₋ₓ with 0<x<1.

In another aspect, the disclosure relates to a MEMS device comprising a hermetically sealed cavity containing a MEMS component, the cavity being formed in a dielectric layer stack having a thickness, whereby the cavity and the dielectric layer are sandwiched between a substrate and a sealing dielectric layer, and whereby the MEMS component is enclosed by a trench extending over the thickness of the dielectric layer stack.

The sealing dielectric is may be selected from the group of silicon-carbides or alumina-oxides when the dielectric layer stack comprises or consists of silicon-oxide.

The MEMS device can further comprise a membrane covering the sealing layer at the location of the cavity, and an electrode covering and filling the trench. The membrane and electrode may be formed in the same material. This material can be silicon-germanium.

These as well as other aspects, advantages, and alternatives, will become apparent to those of ordinary skill in the art by reading the following detailed description, with reference where appropriate to the accompanying drawings.

### BRIEF DESCRIPTION OF THE FIGURES

Various exemplary embodiments are described herein with reference to the following drawings, wherein like numerals denote like entities. The drawings described are schematic and are non-limiting.

FIG. 1 shows a schematic cross-section of a partial processed MEMS device according to this disclosure.

FIG. 2 shows a schematic top view of the MEMS device shown in FIG. 1.

FIG. 3 shows a schematic cross-section of a MEMS device according to this disclosure.

FIG. 4 shows a schematic cross-section of a MEMS device according to this disclosure

FIG. 5 shows a schematic top view of a MEMS device shown in FIG. 4

FIG. 6 shows a schematic cross-section of a MEMS device according to this disclosure

FIGS. 7-14 illustrate by means of schematic cross-sectional views process steps for manufacturing a MEMS device according to this disclosure.

FIGS. 15-16 illustrate by means of schematic cross-sectional views process steps for manufacturing a MEMS device according to this disclosure

The table below list the reference numbers used throughout the different figures:

TABLE 1
list of reference numbers used

| | |
|---|---|
| 1 | MEMS device |
| 2 | carrier substrate |
| 3 | dielectric stack wherein cavity 5 is created |
| 4 | sealing dielectric |
| 5 | cavity comprising MEMS component 6 |
| 6 | MEMS component |
| 7 | membrane overlying cavity 5 |
| 8 | trench through sealing dielectric 4 and dielectric |
| | stack 3 exposing part of the carrier substrate 2 |
| 9 | electrode to carrier substrate 2 |
| 10 | electrode to MEMS component 6 |
| 11 | 1^{st} layer of dielectric stack 3 |
| 12 | 2^{nd} layer of dielectric stack 3 |
| 13 | Isolation trench in membrane-electrode layer 18 |
| 14 | membrane sealing |
| 15 | metal contact to electrode 8, 10 |
| 16 | structural layer for forming MEMS component 6 |
| 17 | release opening in membrane 7 |
| 18 | membrane - electrode layer |
| 19 | opening trough sealing dielectric 4 and dielectric |
| | stack 3 exposing part of MEMS component 6 |
| 20 | trench sealing |
| 21 | Opening through sealing dielectric 4 and dielectric |
| | stack 3 exposing part of the carrier substrate 2 |

### DETAILED DESCRIPTION

The present invention will be described with respect to particular embodiments and with reference to certain drawings but the invention is not limited thereto but only by the claims. The drawings described are schematic drawings. In the drawings, the size of some of the elements may be exaggerated and not drawn on scale for illustrative purposes. The dimensions and the relative dimensions do not necessarily correspond to actual reductions to practice of the invention.

Furthermore, the terms first, second, third and the like in the description and in the claims, are used for distinguishing between similar elements and not necessarily for describing a sequential or chronological order. The terms are interchangeable under appropriate circumstances and the embodiments of the invention may operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein may operate in other orientations than described or illustrated herein.

The term “comprising”, used in the claims, should not be interpreted as being restricted to the elements or steps listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the disclosure and claims, at least the components A and B are part of the device.

In an example aspect, the disclosure relates to a MEMS device 1 comprising a cavity 5 containing a MEMS component 6, the cavity 5 being formed in a dielectric layer stack 3 having a thickness t_{d}, whereby the cavity 5 and the dielectric layer stack 3 are sandwiched between a substrate 2 and a sealing dielectric layer 4 having a thickness tₛ, and whereby the MEMS component 6 is enclosed by at least one trench 8 extending over the thickness t_{d} of the dielectric layer stack 3 and of the sealing dielectric tₛ.

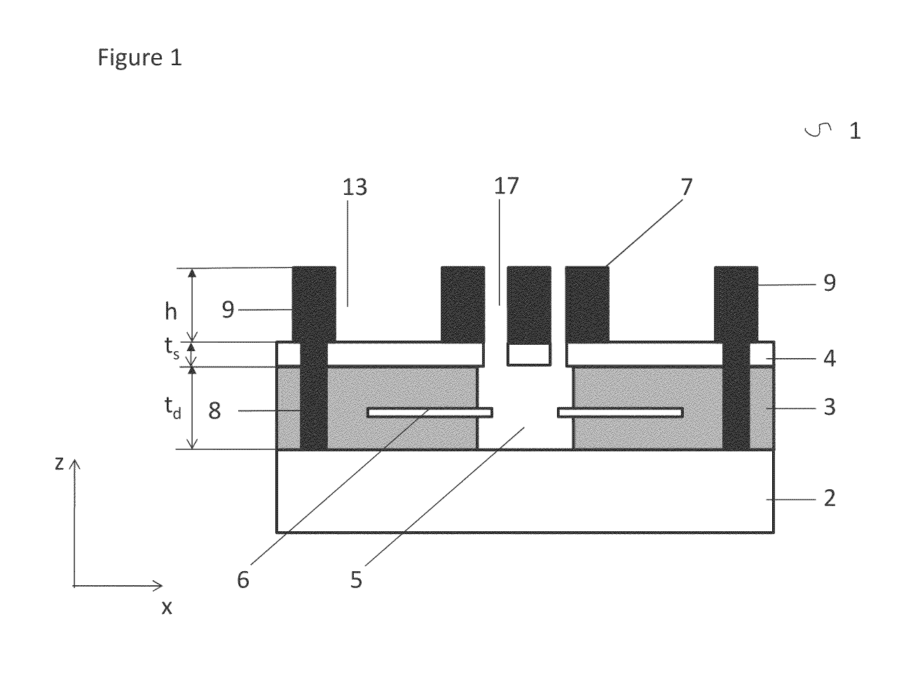

Such a device is illustrated by FIGS. 1 to 3. The cavity 5 is created in a dielectric layer stack 3. A MEMS component 6, e.g. a cantilever, extends from this dielectric layer stack 3 into the cavity 5. A membrane 7 overlies and seals the cavity 5 which is accessible via openings 17 in the membrane 7. At least one electrode 9 contacts the carrier substrate 2 via a trench 8 through the dielectric layer stack 3. The electrode 9 is separated from the membrane 7 by an isolation trench 13.

In order to preserve the ambient within the cavity 5 and to prevent leakage from the environment through the dielectric stack 3 into the cavity 5, in particular during operation of the MEMS device 1, that part of the dielectric stack 3 containing the MEMS component 6 and the cavity 5 is bordered by materials providing a better sealing, at least towards hydrogen, than the dielectric stack 3.

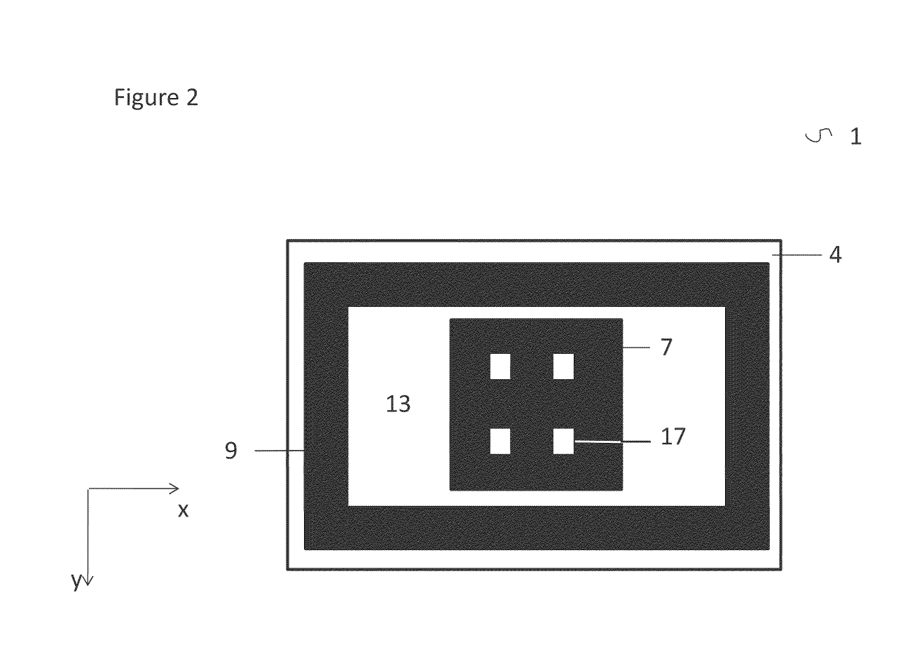

In a direction z perpendicular to substrate 2, this sealing is provided for by the carrier substrate 2 at one side and by the sealing dielectric 4 and the membrane 7 on the opposite side. The sealing dielectric 4 is on the dielectric stack 3 while the membrane 7 is on the sealing dielectric 4. As shown in FIG. 2, the openings 17 in the membrane 7, extending to the sealing dielectric 4, are closed by a membrane sealing 14. As the sealing dielectric 4 is covering the dielectric stack 3, it provides a uniform sealing thereof at this side. If openings 8, 17 are created in this sealing dielectric 4, these openings are further sealed by e.g. the electrode 9 and by the membrane sealing 14.

In a direction x parallel to the substrate 2 this sealing is provided for by at least one trench 8 extending at least over the thickness t_{d} of the dielectric stack 3. This trench 8 encircles the MEMS component 6 and is filled with a material different than the material of the dielectric stack 3.

FIG. 2 shows a schematic top view of the MEMS device 1 of FIG. 1. On the sealing dielectric 4, the membrane 7 and the electrode 9 can be seen. The membrane 7 contains openings 17 to the cavity 5. As explained in another example aspect of the disclosure, these openings 17 allow selective removal of the dielectric stack 3 at the location of the MEMS component 6 to create the cavity 5 thereby releasing the MEMS component 6. The layout of the membrane 7 may depend on the MEMS device 1 to be formed and is not limited to the particular design shown in FIG. 2. Likewise the number, distribution and layout of the openings 17 may depend on the MEMS device 1 and are not limited to the particular design shown in FIG. 2.

Surrounding the membrane 7 and spaced apart there from by an isolation trench 13, the electrode 9 is present configured as a closed ring. The layout of the electrode 9 and of the trench 8 filled by this electrode 9 may depend on the MEMS device 1 to be formed and is not limited to the particular design shown in FIG. 2. This electrode 9 can be used to bias the substrate 2, e.g. to provide a ground-connection to the substrate.

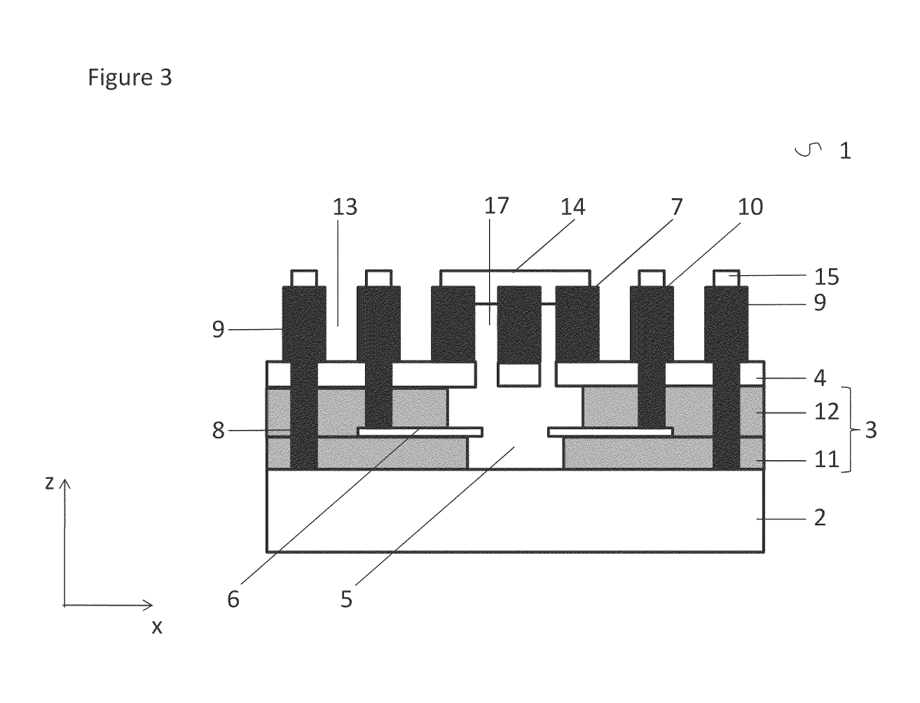

FIG. 3 shows a schematic cross-section of a MEMS device 1. In addition to the MEMS device shown in FIGS. 1 and 2, an electrode 10 to the MEMS component 6 can also be present. This electrode 10 can be used to supply voltages to the MEMS component 6. A metallic contact 15 is formed on the MEMS component electrode 10 and on the substrate electrode 9 to obtain a better electrical contact with the electrode material. Openings 17 in the membrane 7 are closed by a membrane sealing 14.

The sealing dielectric 4 may be selected from the group of silicon-carbides or alumina-oxides when the dielectric layer stack 3 comprises or consists of silicon-oxide. The latter may be the case if a semiconductor-on-insulator substrate is used for micromachining the MEMS component 6. A semiconductor-on-insulator substrate is composed of a thin semiconductor layer isolated from a thicker semiconductor substrate by a dielectric layer. Typically this semiconductor substrate is a silicon substrate, whereby this dielectric layer is a silicon-oxide layer. The MEMS component is micromachined in the thin semiconductor layer which is used as structural layer 16. The insulating layer becomes part of the dielectric stack 3, and, when it is formed of silicon-oxide, it may constitute a leakage path.

Compared with the 0.3 eV activation energy of silicon-oxide, materials such as silicon-carbide, e.g. SiC, and alumina-oxide, e.g. Al₂O₃, have a relatively high activation energy, respectively 3 eV and 1 eV, for the diffusion of hydrogen. This activation energy can be increased by densifying the silicon-oxide, but this would require temperatures above 500° C. which is incompatible with MEMS micromaching.

The membrane 7 and the electrode 9 may be formed in the same material, and may also be in the same layer of material. This membrane and electrode material can be silicon-germanium SiₓG₁₋ₓ with 0<x<1.

If the membrane 7 and the electrode 9 are formed in the same layer, they will protrude to the same height h from the sealing dielectric 4. The upper surfaces of the membrane 7 and the electrode 9 are then coplanar.

In the FIGS. 1 to 3, only one sealing trench 8 is shown. The sealing efficiency can be further improved if more than one sealing trench 8 filled with electrode material encircles the MEMS component 6. These sealing trenches 8 may be concentric with the cavity 5. These sealing trenches 8 can be overlapped by a single electrode 9 or every trench 8 can be overlapped by a separate electrode 9.

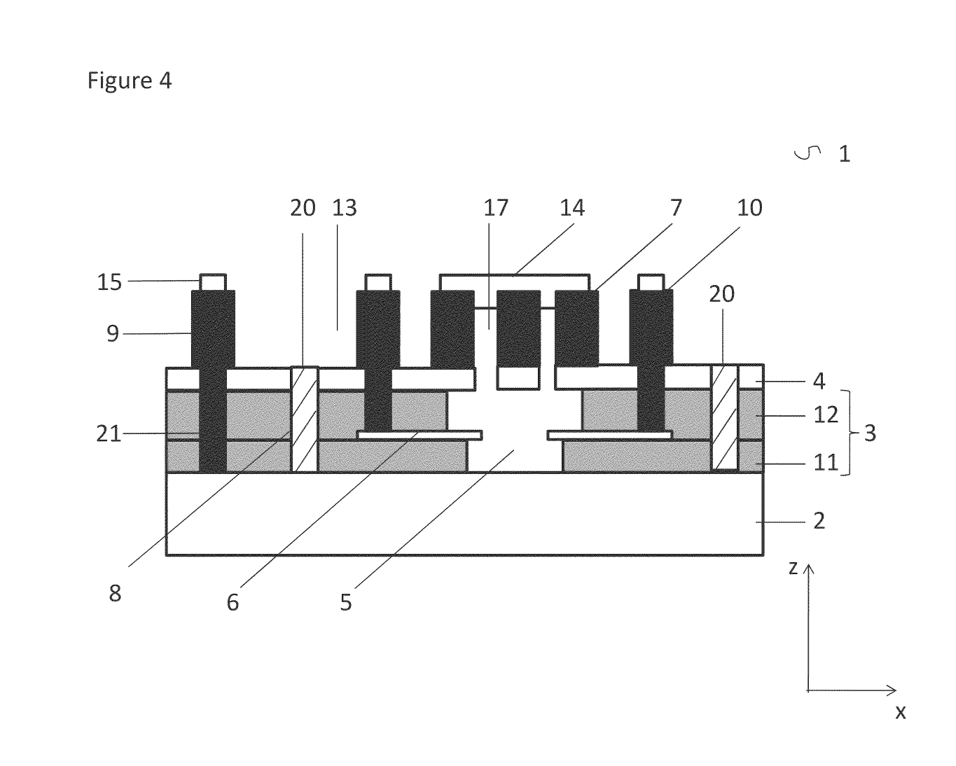

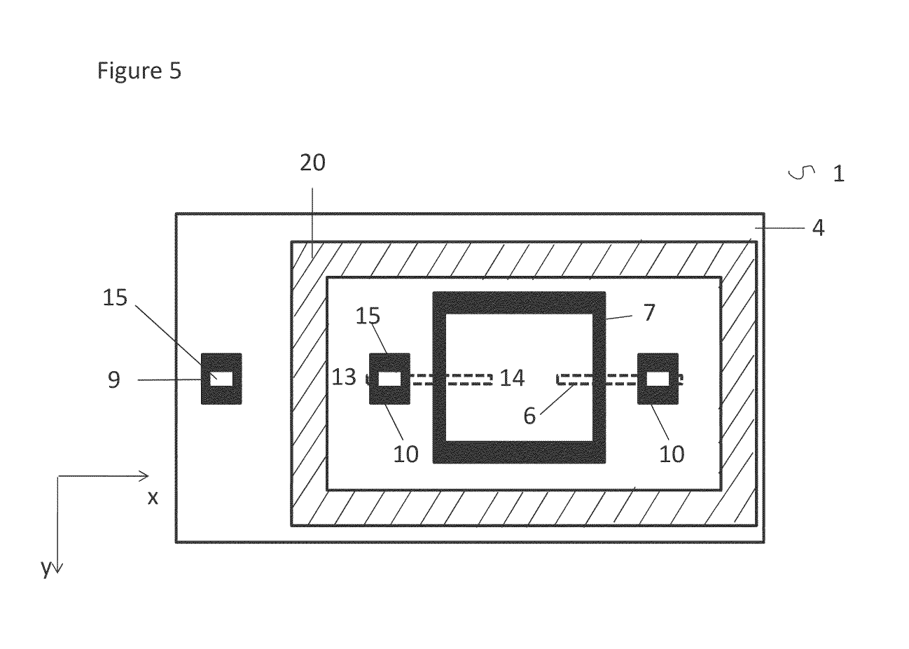

In the MEMS devices 1 illustrated by FIGS. 1 to 3, the electrode 9 filling the trench 8 provided at the same time an electrical contact to the substrate 2 and an improved sealing in lateral direction of the enclosed cavity 5. In the MEMS device illustrated by FIGS. 4 to 6, the electrical substrate contact and the lateral cavity sealing are formed respectively in an opening 21 and in trench 8. In addition to the MEMS device 1 shown in FIG. 3, the MEMS device 1 of FIG. 4 contains a substrate electrode 9 and a filled sealing trench 20. The top view in FIG. 5 illustrates that the filled sealing trench 20 encircles the MEMS component 6, shown by the dotted line. By creating an opening 21 and a trench 8, one can individually optimize the layout of the trench 8—opening 21 and/or the fill material 9, 20 in function of the required functionality such as electrical contact, sealing properties. The sealing trench 20 can be filled up to the upper surface of the sealing dielectric 4 as shown in FIG. 4 or can extend above the sealing dielectric 4.

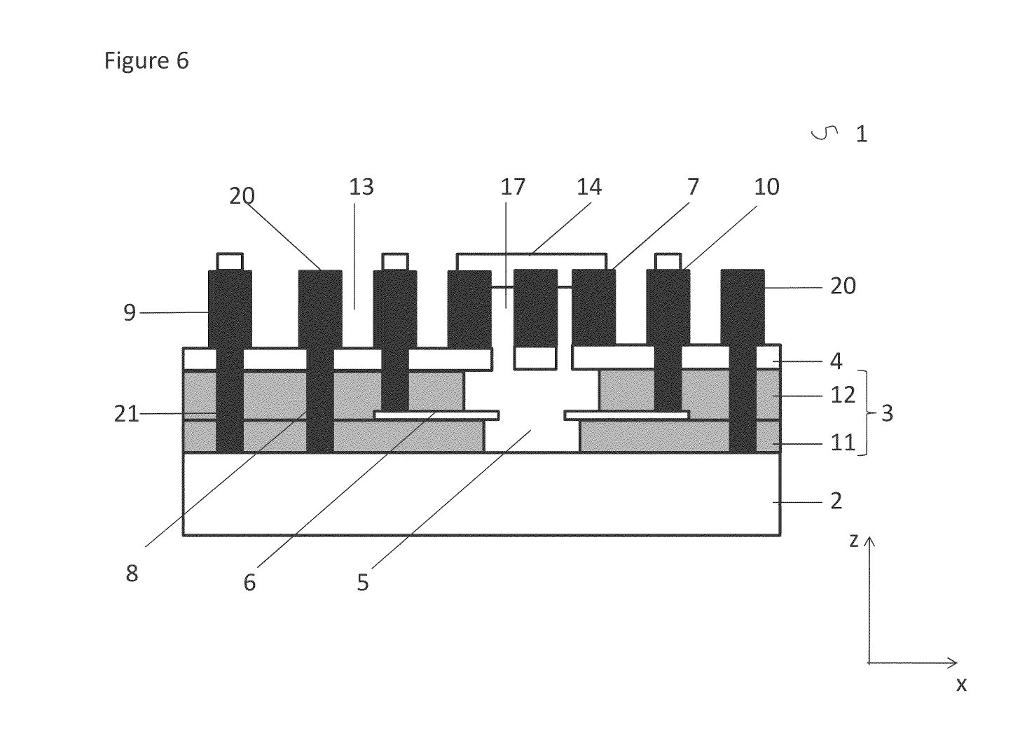

In the MEMS device 1 illustrated by FIGS. 4 and 5, the trench 8 surrounding the MEMS component 6 was filled 20 with a material other than the material used to form the substrate electrode 9 and/or the membrane 7. For ease of processing, one might still choose to use the same material to fill the substrate electrode trench 8-9, the sealing trench 8-20, the MEMS component trench 19 and to form the membrane 7 as shown in FIG. 6.

In another example aspect, the disclosure relates to a method of manufacturing a MEMS device 1 comprising a cavity 5 containing a MEMS component 6, the cavity 5 being formed in a dielectric layer stack 3 having a thickness t_{d}, whereby the cavity 5 and the dielectric layer stack 3 are sandwiched between a substrate 2 and a sealing dielectric layer 4 having a thickness tₛ, and whereby the MEMS component 6 is enclosed by at least one trench 8 extending over the thickness t_{d} of the dielectric layer stack 3 and of the sealing dielectric tₛ.

The method comprises providing a substrate 2 having upon a major surface a dielectric layer stack 3, whereby a MEMS component 6 is embedded in the dielectric stack 3. The method further comprises forming a sealing dielectric 4 overlying the dielectric stack, forming at least one trench 8 enclosing the MEMS component 6 and extending to the substrate 2 and filling the trench 8 with a material different from the dielectric stack 3.

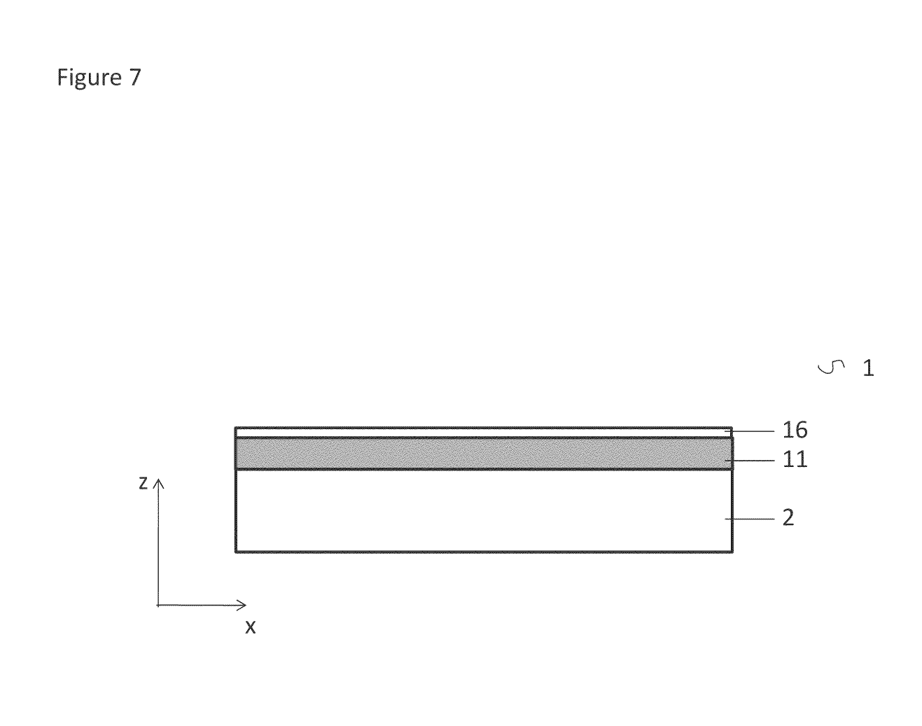

FIGS. 7 to 14 illustrate a method for manufacturing such a MEMS device 1.

On a substrate 2 a first dielectric layer 11 is formed. On this dielectric layer 11 a structural layer 16 is formed. Such a layered substrate is illustrated by FIG. 7. The layered substrate can be a semiconductor-on-insulator substrate composed of a thin semiconductor layer isolated from a thicker semiconductor substrate by a dielectric layer. Typically this semiconductor substrate is a silicon substrate, whereby this dielectric layer is a silicon-oxide layer. The MEMS component will then be micromachined in the thin semiconductor layer which is used as structural layer 16. The insulating layer will constitute the first dielectric layer 11 and become part of the dielectric stack 3, and, when formed of silicon-oxide, it may constitute a leakage path.

The structural layer 16 is patterned to form the MEMS component 6. The layout of this MEMS component 6 may depend on the MEMS device 1 to be formed and is not limited to the particular design shown in FIGS. 7-14. Overlying this MEMS component a second dielectric layer 12 is formed. This second dielectric layer 12 can comprise or consist of silicon-oxide. The first 11 and second 12 dielectric layers form the dielectric stack 3 having a thickness t_{d}.

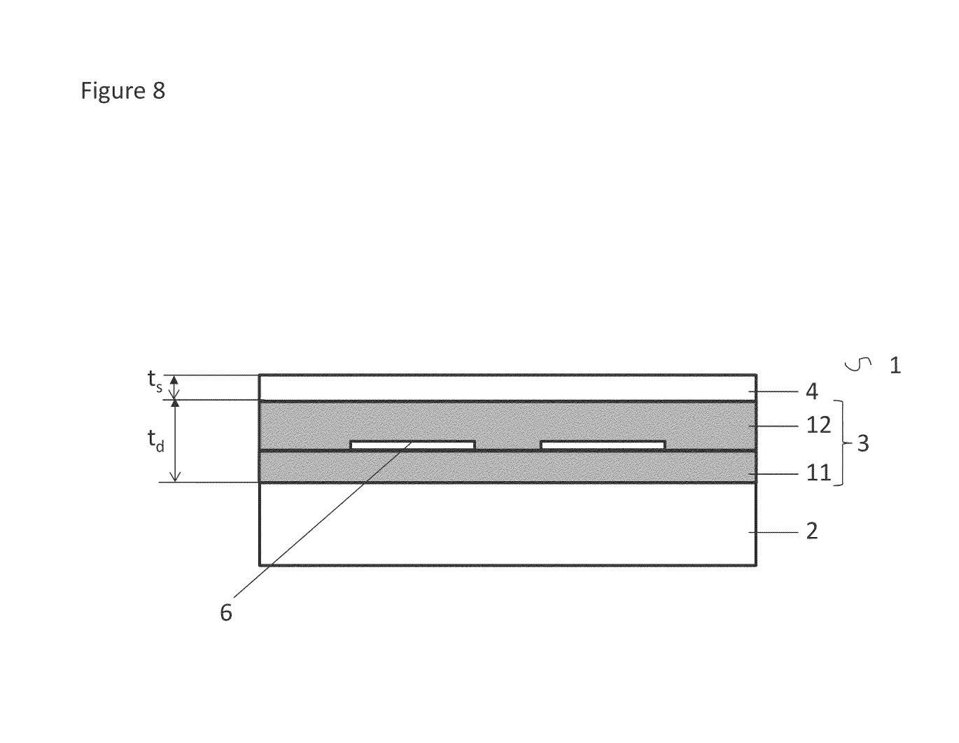

On this dielectric stack 3 the sealing dielectric 4 is formed having a thickness t₂. This sealing dielectric 4 provides a uniform sealing of the upper surface of this dielectric stack 3. As shown in FIG. 8 the dielectric stack 3, wherein the MEMS component 6 is embedded, is sandwiched between the substrate 2 and the sealing dielectric 4 thereby providing sealing of the dielectric stack 3 in a direction z perpendicular to the substrate 2.

The sealing dielectric 4 may be selected from the group of silicon-carbides or alumina-oxides when the dielectric layer stack 3 comprises or consists of silicon-oxide.

Compared with silicon-oxide, materials such as silicon-carbide, e.g. SiC, and alumina-oxide, e.g. Al₂O₃, have a relatively high activation energy, respectively 3 eV and 1 eV, for the diffusion of hydrogen.

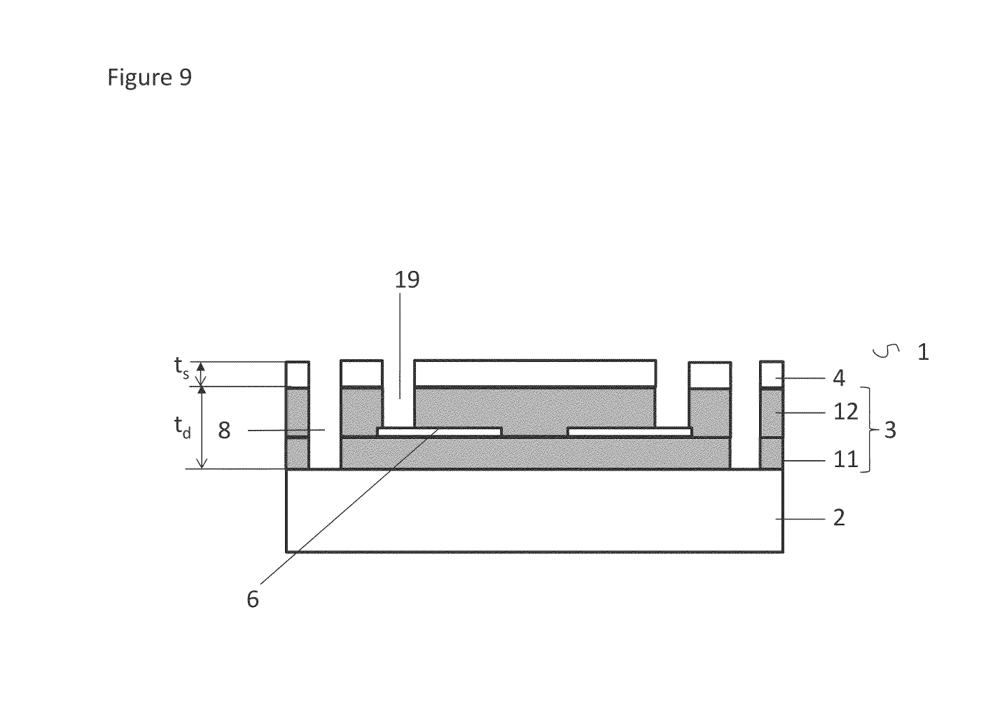

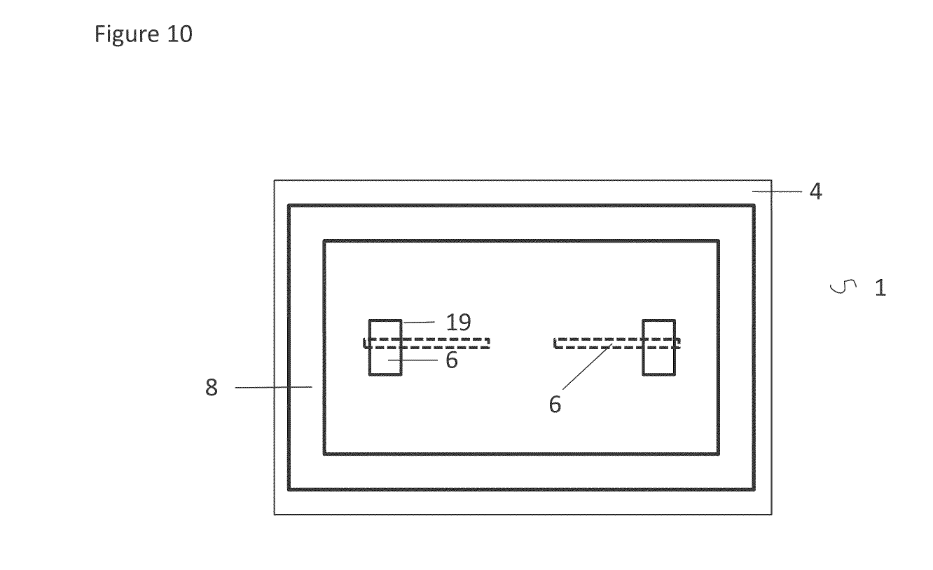

Openings 8 are formed in the sealing dielectric 4 and in the dielectric stack 3 to expose part of the substrate 2. In an example, openings 19 can also be formed in the sealing dielectric 4 and the dielectric stack 3 to expose part of the MEMS component 6 as shown in FIG. 9. The top view shown in FIG. 10 clearly illustrates that the opening 8 is a trench configured as a closed ring surrounding the MEMS component 6 (indicated by the dotted line) while the opening 19 is a hole providing access to the MEMS component 6.

After creating the trench 8 this trench is filled and a membrane 7 is formed on the sealing dielectric 4 at the location where the cavity 5 is to be formed.

The membrane 7 and the trench fill may be formed in the same material, and may also be in the same layer of material. This membrane and trench fill material can be silicon-germanium SiₓG₁₋ₓ with 0<x<1.

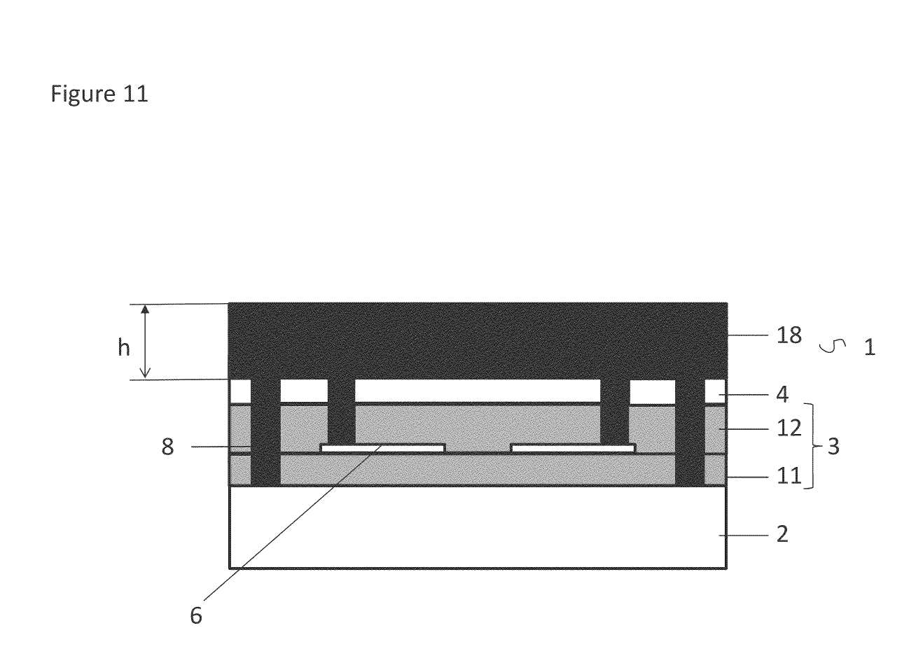

FIG. 11 illustrates the case where the membrane 7 and the trench fill are formed in the same layer of material 18. All openings 8, 19 are filled when depositing this layer 18 having a height h above the sealing dielectric 4.

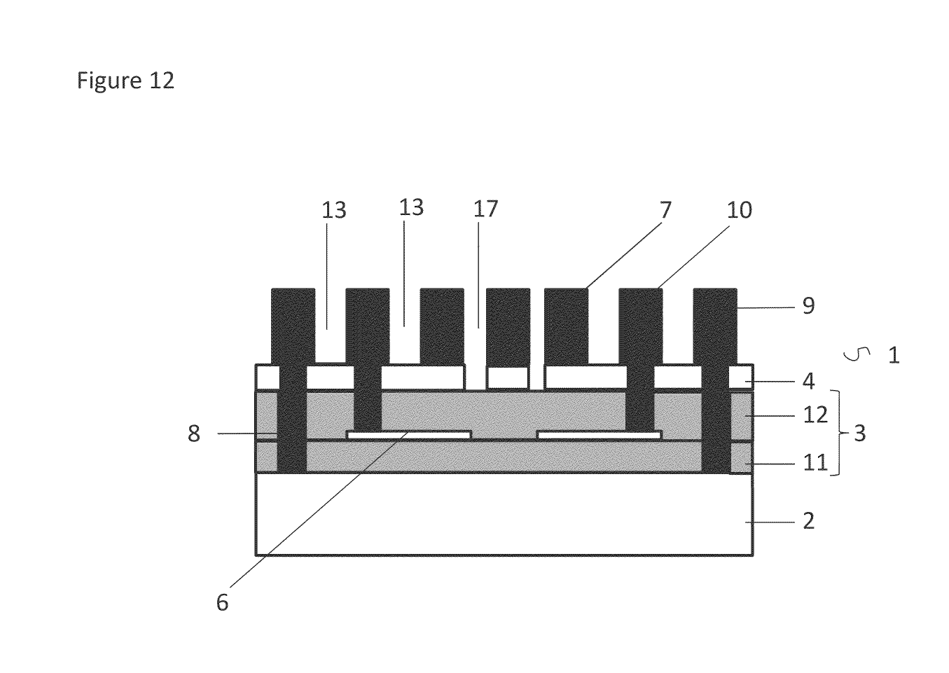

After depositing the layer 18 as shown in FIG. 10, this layer 18 is patterned to create the membrane 7, the electrode 9 filling and overlying the sealing trench 8 and the electrode 10 filling and overlying the opening 19. The membrane 7 and the electrodes 9, 10 are mutually isolated by the isolation trenches 13 exposing the sealing layer 4. No leakage towards the cavity 5 can occur via these isolation trenches 13 as at the bottom thereof the sealing dielectric 4 is present aligned to and even extending beyond the area of the isolation trench 13 as shown in FIG. 12.

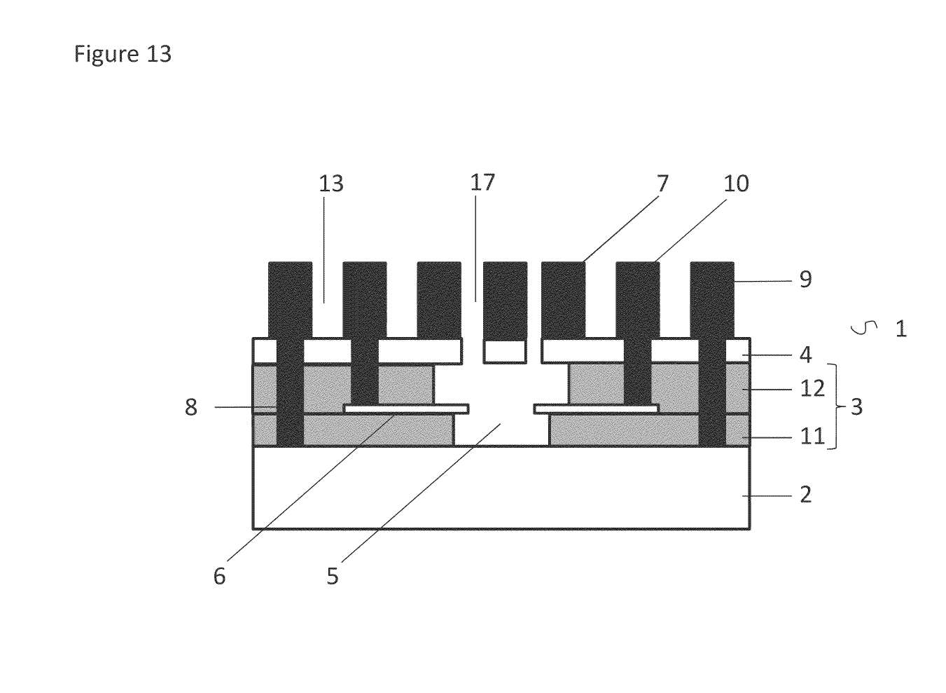

The openings 17 in the membrane 7 are extended through the sealing dielectric 4 thereby exposing the dielectric stack 3 as shown in FIG. 12. Through these openings the dielectric stack 3 can be locally removed thereby creating the cavity 5 and releasing the MEMS component 6 as shown in FIG. 13. As the sealing dielectric 4 provides sealing functionality also in the areas outside the membrane 7, the cavity can extend even beyond the area of the membrane 7 thereby giving more freedom in the layout and the position of the membrane 7.

The dielectric stack 7 may be removed selectively with respect to the sealing dielectric 4 in order not to affect the sealing functionality thereof. If the sealing dielectric 4 is selected from the group of silicon-carbides or alumina-oxides and the dielectric layer stack 3 comprises or consists of silicon-oxide, the openings 17 in the sealing dielectric 4 can be created by dry etch stopping on the dielectric stack 3 while selective removal of this dielectric stack 3 can be done using a wet or vapor phase HF based etchant.

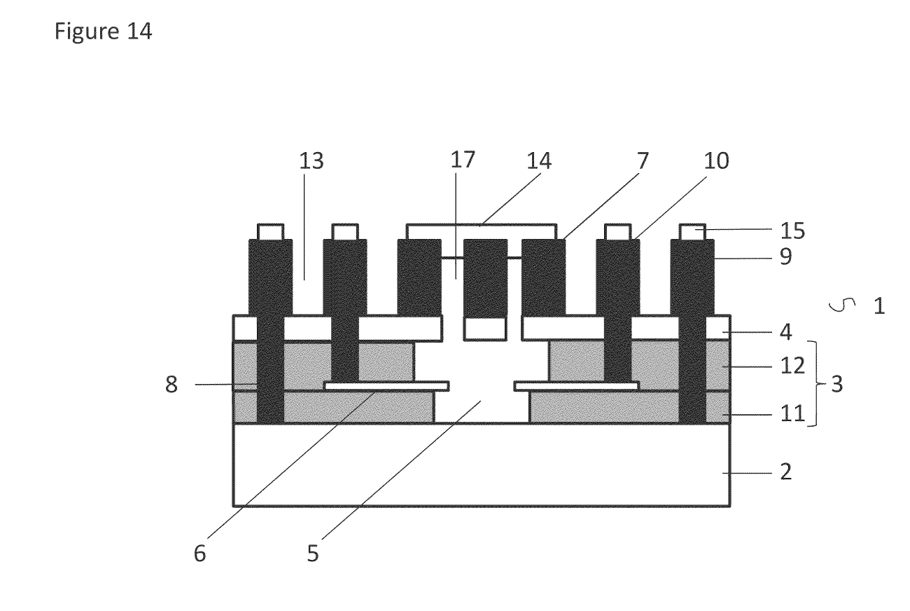

After releasing the MEMS component 6, the sealing of the cavity 5 is finished by a sealing process forming a sealing 14 covering the release holes 17 in the membrane 7 as shown in FIG. 14.

The process sequence illustrated by FIGS. 7 to 14 may be slightly modified if MEMS devices 1 as shown in FIG. 4 to 5 or 6 are to be manufactured.

If a MEMS device according to FIG. 6 is to be fabricated, the patterning step as shown in FIG. 9 is slightly modified. The patterning step then also includes forming a dielectric opening 21 for receiving the membrane—electrode layer 18 during the deposition thereof.

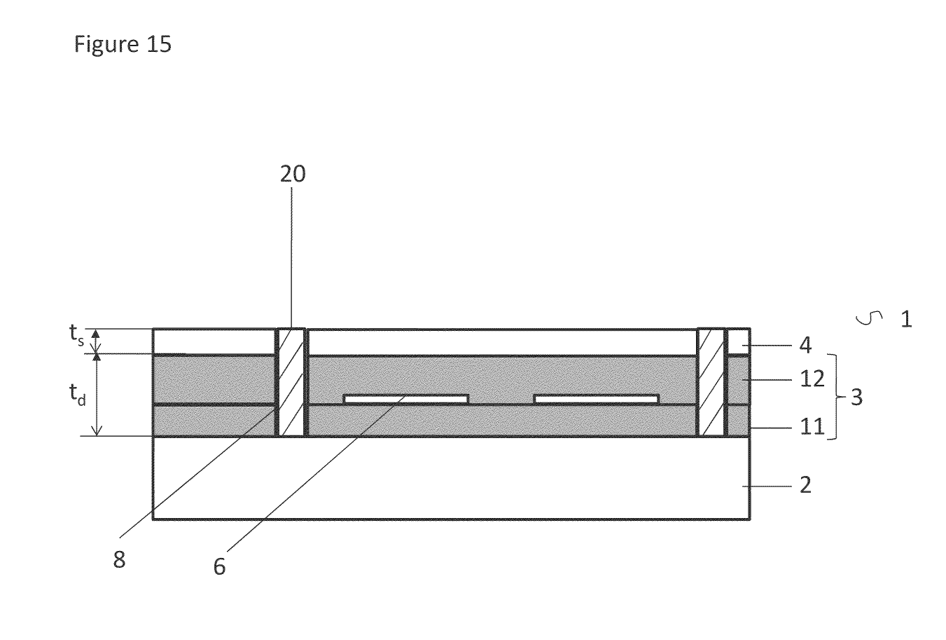

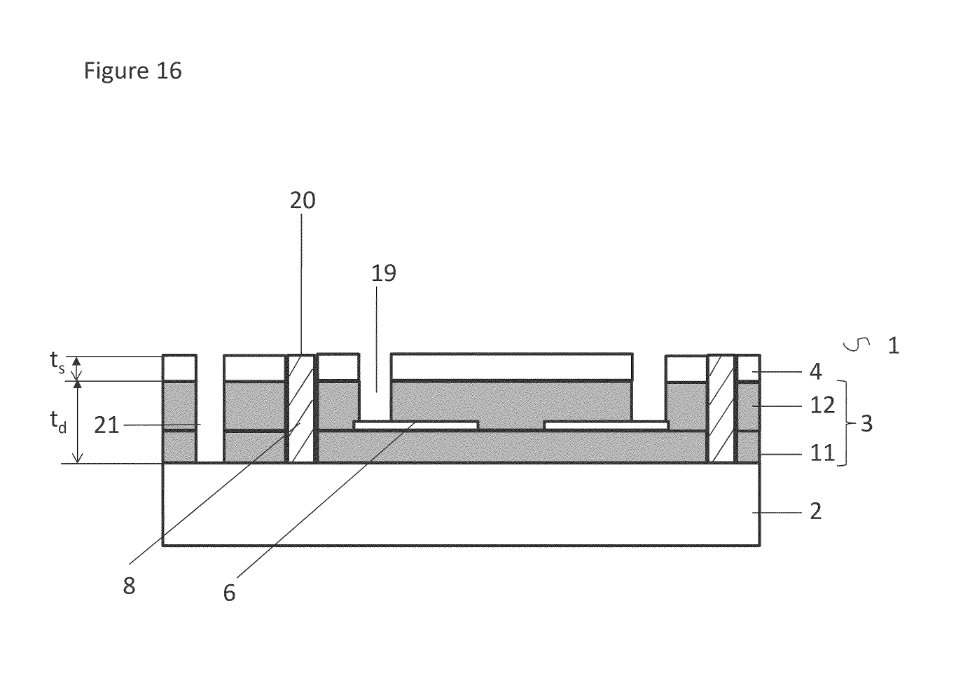

If a MEMS device 1 according to FIGS. 4-5 to be fabricated, at least one additional patterning step and deposition step is to be included in the process flow. After depositing the sealing dielectric 4 a patterning step is performed to create the sealing trench 8. The sealing trench 8 will be filled 20 with a material providing the desired sealing properties and being compatible with the MEMS processing. The filled trench 20 is planar with the sealing dielectric 4. FIG. 15 illustrate the MEMS device after creating and filling the sealing trench 8. Then the process flow can be continued by patterning the dielectric opening 21 for receiving the substrate electrode 9 and the contact opening 19 for receiving the MEMS component electrode 10 as shown in FIG. 16. The membrane-electrode layer 18 is deposited thereby filling the openings 19 and 21 as is done in FIG. 11.

A hermetic sealed cavity 5 is thus fabricated eliminating the possible leakage paths due to the presence of silicon-oxide in the dielectric stack 3. In addition this sealing also can provide an electrical connection 9 to the substrate 2.

Further processing of the sealed MEMS device 1 can be done using known manufacturing techniques to provide e.g., forming the electrical connections 15 to the electrodes 9, 10 and dicing of the individual packaged MEMS devices.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims, along with the full scope of equivalents to which such claims are entitled. It is also to be understood that the terminology used herein is for the purpose of describing particular embodiments only, and is not intended to be limiting.

1. A method for manufacturing a MEMS device comprising a hermetically sealed cavity containing a MEMS component, the method comprising:
providing a substrate having, on a major surface, a stack of a structural layer on a first dielectric layer;
patterning the structural layer to form a MEMS component;
forming a second dielectric layer overlying the MEMS component;
forming a sealing dielectric layer overlying the second dielectric layer;
forming, in the stack of dielectric layers, a trench enclosing the MEMS component thereby extending to the substrate;
depositing a membrane layer overlying the sealing layer thereby filling the trench; and
patterning the membrane layer thereby forming a membrane at the location of the cavity and an electrode covering the filled trench.

2. The method of claim 1, further comprising removing the first and second dielectrics selective to the sealing dielectric layer, thereby forming the cavity which contains the MEMS component.

3. The method of claim 2, further comprising forming openings through the membrane and the sealing dielectric layer at the location of the MEMS component, through which openings the first and second dielectrics are removed.

4. The method of claim 3, further comprising closing the openings in the membrane after the selective removal of the first and second dielectric.

5. The method of claim 1, wherein the sealing dielectric is selected from the group consisting of silicon-carbides and alumina-oxides, and wherein the first and second dielectrics are silicon-oxide.

6. The method of claim 1, wherein the membrane layer is a silicon-germanium layer.

7. The method of claim 1, wherein the substrate is a Semiconductor-On-Insulator (SOI) substrate and the semiconductor layer thereof is the structural layer.

8. A MEMS device comprising:
a dielectric layer stack having a thickness; and
a hermetically sealed cavity containing a MEMS component and formed in the dielectric layer stack, wherein the hermetically sealed cavity and the dielectric layer are sandwiched between a substrate and a sealing dielectric layer, and wherein the MEMS component is enclosed by a trench extending over the thickness of the dielectric layer stack.

9. The MEMS device of claim 8, wherein the sealing dielectric is selected from the group consisting of silicon-carbides and alumina-oxides, and wherein the dielectric layer stack comprises silicon-oxide.

10. The MEMS device of claim 8, further comprising a membrane covering the sealing layer at the location of the cavity and an electrode covering and filling the trench.

11. The MEMS device of claim 10, wherein the membrane and electrode are formed in the same material

12. The MEMS device of claim 11, wherein the same material is silicon-germanium.

13. The MEMS device of claim 9, further comprising a membrane covering the sealing layer at the location of the cavity and an electrode covering and filling the trench.
